(19) United States
(12) Patent Application Publication
(10) Pub. No.: US 2011/0104904 A1
(43) Pub. Date: May 5, 2011

(54) METHOD OF PROCESSING SILICON WAFER

(75) Inventor: Shigeki Nishimura, Yamaguchi (JP)

(73) Assignee: SILTRONIC AG, Munich (DE)

(21) Appl. No.: 12/916,695

(22) Filed: Nov. 1, 2010

(30) Foreign Application Priority Data
Nov. 2, 2009 (JP) 2009-252014

(51) Int. Cl. H01L 21/306

(52) U.S. Cl. 438/745; 257/E21.219

(57) ABSTRACT

A method of processing a silicon wafer including sequentially carrying out the steps of (1) preparing a lapped semiconductor silicon wafer, (2) cleaning the wafer with a surfactant, (3) cleaning the wafer with alkali or acid, and (4) etching the wafer with high-purity sodium hydroxide.

### CROSS REFERENCE TO RELATED APPLICATIONS

This application claims priority from Japanese Patent Application No. JP 2009-252014, filed on Nov. 2, 2009, which is incorporated by reference herein in its entirety.

### FIELD

The present invention relates to a method of processing a silicon wafer.

### BACKGROUND

When a silicon wafer used for integrated circuits such as IC and LSI or individual semiconductor elements such as transistors and diodes is to be manufactured, a single crystal obtained by the Czochralski method (CZ method) or the floating zone method (FZ method) is cut by using an inner diameter blade cutting machine or a wire saw, its peripheral part is subjected to beveling processing, and its principal surface is subjected to lapping processing using loose abrasive grains in order to improve flatness. Then, a cleaning process for removing the contamination applied to the wafer during these processes is carried out. Further, wet etching for removing processing strain and, subsequently, mirror polishing is carried out. Examples of the wet etching which removes the processing strain include alkali etching which uses an alkali such as sodium hydroxide or potassium hydroxide (Japanese Patent Application Disclosure No. 2005-210085). Said alkali etching has the advantage that, since its etching rate is low, a wafer can be obtained that has good flatness after etching. On the other hand, said alkali etching has the disadvantage that a metal impurity contained in the alkali etching solution diffuses into the wafer during the alkali etching.

Recently, in order to resolve the above-mentioned disadvantage, a technique which uses an ultrahigh-purity sodium hydroxide solution as the alkali etching solution has been developed (Japanese Patent Application Disclosure No. 2005-210085). However, regarding the case when said ultrahigh-purity sodium hydroxide etching solution is used, although contamination with heavy metals, etc. can be sufficiently prevented, the techniques for preventing wafer flatness deterioration after etching have not been satisfactory.

### BACKGROUND

An aspect of the present invention is to provide a method of preventing wafer flatness deterioration after etching even when the ultrahigh-purity sodium hydroxide etching solution is used.

In an embodiment, the present invention provides method of processing a silicon wafer by sequentially carrying out the following steps:

(1) preparing a lapped semiconductor silicon wafer;

(2) cleaning the wafer with a surfactant;

(3) cleaning the wafer with alkali or acid; and

(4) etching the wafer with high-purity sodium hydroxide.

### BACKGROUND

Embodiments of the present invention are described in detail below with reference to the drawings, in which:

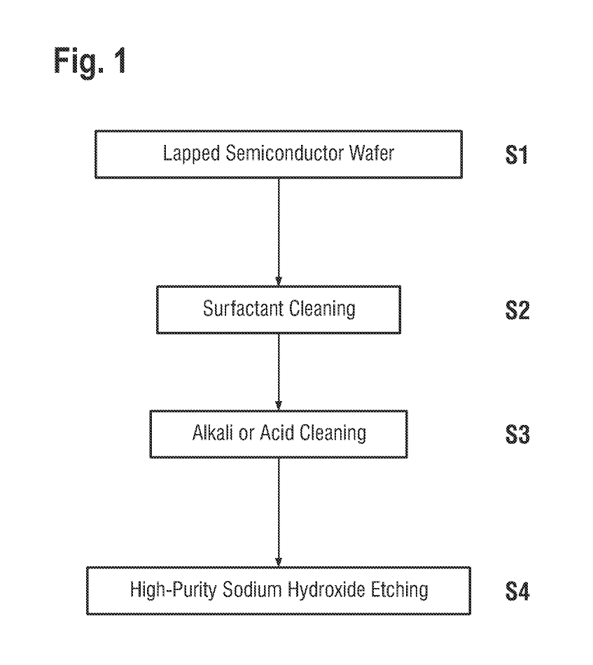

FIG. 1 represents a process chart showing the method according to the present invention.

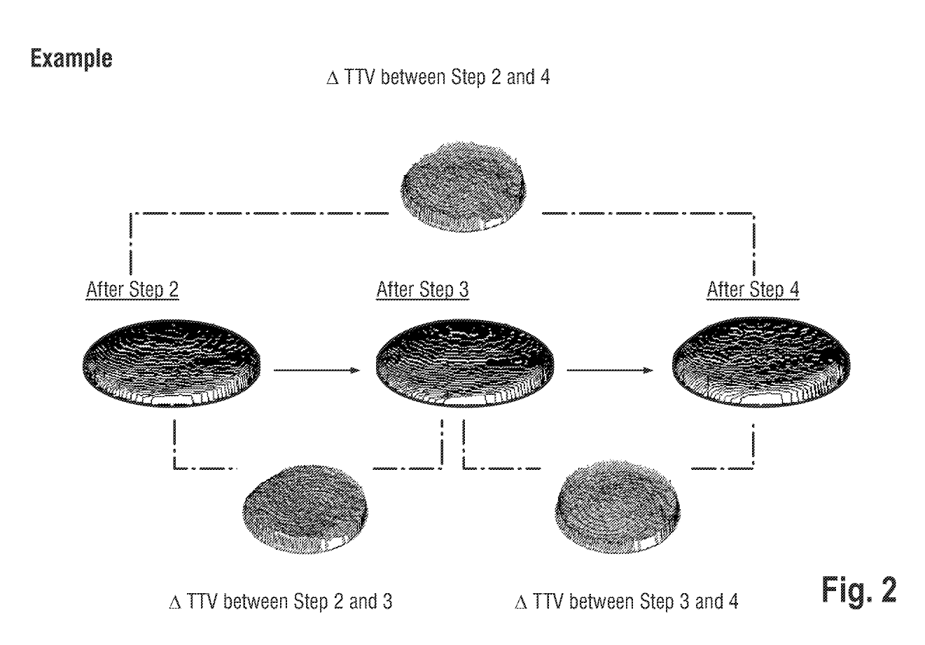

FIG. 2 represents a drawing showing analysis results obtained in an example.

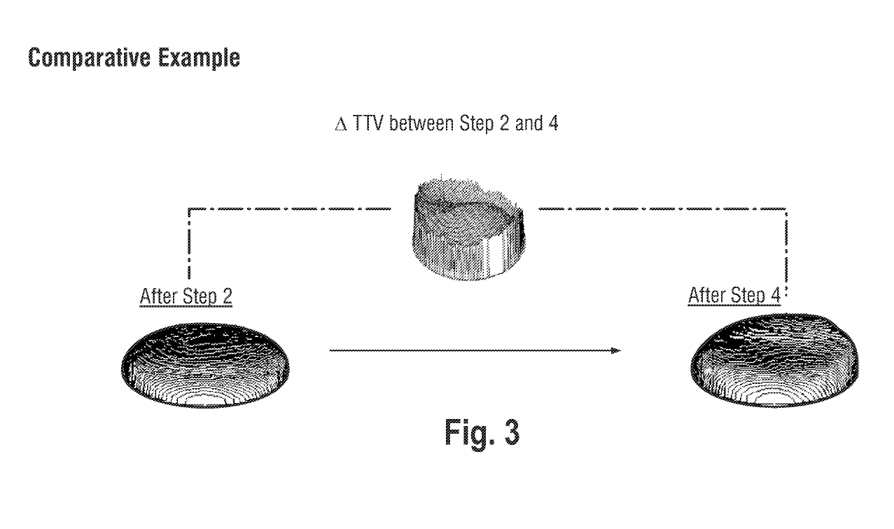

FIG. 3 represents a drawing showing analysis results obtained in a comparative example.

FIG. 1 is a process chart showing the method of the present invention.

### DETAILED DESCRIPTION

The present inventor diligently carried out research and development in order to find a method for preventing wafer flatness deterioration after an etching process in which the above-explained ultrahigh-purity sodium hydroxide etching solution is used. As a result, the present inventor found that said wafer flatness deterioration can be sufficiently prevented by carrying out two cleaning processes after lapping and before the etching with the ultrahigh-purity sodium hydroxide solution.

In a method according to an embodiment of the invention, two cleaning processes are carried out after lapping and before the etching with a high-purity sodium hydroxide solution; as a result, the wafer flatness deterioration after etching can be prevented. Thus, an excellent semiconductor wafer free from contamination with metal, etc. and flatness deterioration can be obtained.

In accordance with an embodiment of the invention, the first step (S1) is a step of preparing a lapped semiconductor silicon wafer. Herein, the lapped semiconductor silicon wafer means a silicon wafer obtained after the usually widely known manufacturing processes of cutting a single crystal by using an inner diameter blade cutting machine or a wire saw, subjecting its peripheral part to beveling processing, and subjecting its principal surface to lapping processing using loose abrasive grains in order to improve flatness. There are no particular limitations regarding the size of the wafer, and a wafer in the range of 125 to 450 mm is applicable.

The second step (S2) is a step of cleaning the lapped semiconductor silicon wafer, which is prepared as described above, with a surfactant. Herein, there are no particular limitations regarding the surfactant which can be used in the present invention, and in this case, cleaning means the cleaning carried out after lapping and before acid or alkali etching, using a usually widely known surfactant. A main object of the cleaning with the surfactant is to clean various contaminants (organic-substance contamination and particle contamination) present on the surface of the lapped semiconductor wafer. Specific examples of the surfactant include surfactants from alkali-based to acid-based. Furthermore, the second step of the present invention also includes a process of cleaning the wafer with pure water after the cleaning with the surfactant. Furthermore, the second step can be repeated a plurality of times if necessary.

The third step (S3) of the present invention is a step of cleaning the semiconductor silicon wafer, which is cleaned with the surfactant as described above, with alkali or acid. The cleaning in the third step includes not only the cleaning of the contaminants (organic-substance contamination and particle contamination) on the surface of the semiconductor silicon wafer, but also the etching of the surface of the semiconductor silicon wafer by a specific amount. An object of the cleaning/etching of the third step is to remove non-uniform contaminants and a process-affected layer, both present on the uppermost surface of the lapped semiconductor wafer. In order to achieve said object, for example, a potassium hydroxide or sodium hydroxide aqueous solution can be used in the case in which alkali is used, and the usage concentration thereof is preferably within the range of 40 to 50 weight %. The amount of etching by the alkali cleaning is preferably within the range of 0.3 to 0.8 μm per side. If the amount is smaller than this, the non-uniform contaminants and process-affected layer present on the uppermost surface of the lapped semiconductor wafer may not be sufficiently removed, and flatness deterioration caused by subsequent alkali etching by high-purity sodium hydroxide etching increases. If the removal amount is larger than this, flatness deterioration caused by the cleaning/etching of the third step itself can become notable. In the case in which acid is used, for example, a mixed acid aqueous solution of hydrofluoric acid and nitric acid can be used, and there are no particular limitations regarding the mixing ratio thereof. The amount of etching by the acid cleaning is preferably in the range of 0.3 to 0.8 μm per side. If the amount is smaller than this, the non-uniform contaminants and process-affected layer present on the uppermost surface of the lapped semiconductor wafer may not be sufficiently removed, and flatness degeneration caused by subsequent alkali etching by high-purity sodium hydroxide etching increases. If the removal amount is larger than this, flatness deterioration caused by the cleaning/etching of the third step itself can become notable.

In an embodiment of the present invention, a potassium hydroxide aqueous solution having a concentration in the range of 40 to 50 weight % is preferably used as the alkali cleaning In this case, the amount of etching is preferably in the range of 0.3 to 0.8 um.

The fourth step (S4) is a step of etching the cleaned semiconductor silicon wafer, which is obtained in the above described manner, with high-purity sodium hydroxide. Herein, carrying out etching by high-purity sodium hydroxide includes using the high-purity sodium hydroxide solution having the below characteristics as an alkali etching solution. Specifically, unlike etching solutions conventionally used for alkali etching of silicon wafers, the alkali etching solution is an alkali aqueous solution having an extremely low content of contained metal impurities. Herein, the metals contained as impurities include both nonionic and ionic forms, and there are also no limitations regarding the types of the metals. In the present invention, the metals include all the metals which are known for being diffused in a wafer by alkali etching and deteriorating the quality of the wafer. In particular, transition metals are included, and iron, nickel, copper, and chromium are particularly relevant among them. A content of metal impurities as small as possible is preferred. In the present invention, the content of metal impurities being extremely small means that the elemental content of Cu, Ni, Mg, Cr is 1 ppb or less, the elemental content of Pb, Fe is 5 ppb or less, the elemental content of Al, Ca, Zn is 10 ppb or less, and chloride, sulfate, phosphate, and nitride compounds are 1 ppm or less.

There are no particular limitations regarding the concentration of the alkali aqueous solution, and an optimal alkali concentration can be arbitrarily selected in order to achieve the desired etching. Specifically, the alkaline component thereof can be in the range of 20 weight % to 70 weight %, preferably 40 weight % to 60 weight %, and more preferably in the range of 50 weight % to 55 weight %.

Also, there are no particular limitations regarding the method of manufacturing said alkali aqueous solution having said extremely low content of metal impurities, and the solution can be obtained by a conventional publicly-known chemical and/or electrochemical method for achieving high purity. Specifically, an electrolysis method, such as that described in Japanese Patent No. 3380658, can be cited as an example thereof. Alternatively, impurities can be removed by a conventional publicly-known method from an alkali aqueous solution manufactured by a conventional method and containing more than 1 ppb of metal impurities, until the amount of the impurities becomes 1 ppb or less. Furthermore, the alkali etching solution can contain various salts (or acids) added for controlling so-called etching unevenness which can be caused on the silicon wafer surface by the above-explained high-purity sodium hydroxide aqueous solution.

There are no particular limitations regarding etching conditions, and the conditions which are set when a usual publicly-known alkali etching solution is used can be preferably used. Specifically, these conditions include the etching concentration, etching solution amount, etching time, temperature, agitation, etc. Furthermore, there are also no particular limitations regarding the apparatus used in the alkali etching method according to the present invention, and an apparatus used in the case in which a usual publicly-known alkali etching solution is used can be preferably used. In particular, attention should be paid to the amount of metal impurities mixed in from the apparatus.

The semiconductor silicon wafer obtained by the method according to the present invention is also extremely excellent with regard to flatness. The flatness of the silicon wafer can be evaluated by various conventional publicly-known measurement means. Specifically, examples of such means include Ultrascan produced by ADE Corp. and MX302 produced by E+H Corp.

The present invention will be explained in further detail by way of a specific example. However, the present invention is not limited to this example.

### EXAMPLE

Wafer Evaluation Test Method:

1) Etching removal amount and wafer flatness. the thickness and shape of the wafer before and after chemical treatment were measured by using Ultragate9700 by ADE Corp.

2) The data obtained under 1) is subjected to analysis concerning shape change (ΔTTV) before and after chemical treatment by using the analysis software Metrotools-II produced by ADE Corp.

A silicon wafer was prepared which had undergone a lapping process (Step 1) and then a process of surfactant cleaning (Step 2) for removing lapping slurry and which had a strained layer caused by mechanical processing.

As Step 3, the prepared wafer was

immersed in a treatment bath in which potassium hydroxide (product of Hayashi Pure Chemical Ind., Ltd.. EL48% potassium hydroxide solution) was maintained at a solution temperature of 100° C. so as to carry out a cleaning treatment for two seconds aiming a material removal of 0.5 μm per side,

subsequently rinsed by immersing it in ultrapure water, and

then dried.

As Step 4, the wafer was

immersed in a treatment bath in which a sodium hydroxide aqueous solution (product of Tsurumi Soda Co. Ltd.. Clearcut-S 48%) prepared by dissolving 0.10 weight % of sodium nitrate (product of Wako Pure Chemical Industries, Ltd.. special grade chemical) was maintained at 85° C. so as to carry out etching treatment for seven minutes aiming a material removal of 12 μm per side,

subsequently rinsed by immersing °it in ultrapure water, and

then dried.

After each of the Steps 2, 3, and 4, the measurement according to the above mentioned Wafer Evaluation Test Method was carried out. Test results thereof are summarized in Table 1. Furthermore, the test results are shown in FIG. 2.

### Comparative Example

The same processes as in the Example, except for Step 3, were carried out. Similarly, after each of the Steps 2 and 4, the measurement shown in the Wafer Evaluation Test Method was carried out.

Test results thereof are summarized in Table 1 and Table 2. Furthermore, the test results are shown in FIG. 2.

TABLE 1
TTV after each Step

| | Example | Comparative Example |
|---|---|---|
| Step 2 [μm] | 0.69 | 1.08 |
| Step 3 [μm] | 0.67 | Not Available |
| Step 4 [μm] | 0.79 | 1.42 |
| Deterioration Amount between | 0.10 | 0.34 |
| Steps 2 and 4 [μm] | | |

TABLE 2
ΔTTV (Analysis using Metrotools-II):
TTV of Removal Amount Distribution

| | Example | Comparative Example |
|---|---|---|
| between Steps 2 and 3 [μm] | 0.25 | Not Available |
| between Steps 3 and 4 [μm] | 0.24 | Not Available |
| Deterioration Amount between | 0.26 | 0.71 |
| Steps 2 and 4 [μm] | | |

The processing method of the present invention can be widely utilized in manufacturing processes of semiconductor wafers, particularly in an alkali etching process after a lapping process.

1. A method of processing a silicon wafer, the method comprising sequentially carrying out the following steps:
(1) preparing a lapped semiconductor silicon wafer;
(2) cleaning the wafer with a surfactant;
(3) cleaning the wafer with alkali or acid; and
(4) etching the wafer with high-purity sodium hydroxide.

2. The method recited in claim 1, wherein the silicon wafer has a size in a range of 125 to 450 mm.

3. The method recited in claim 1, wherein step (2) includes cleaning the wafer with water after the cleaning with surfactant.

4. The method recited in claim 1, wherein step (2) is repeated at least once.

5. The method recited in claim 1, wherein step (3) includes cleaning with an alkali, the alkali being a potassium hydroxide or sodium hydroxide aqueous solution.

6. The method recited in claim 5, wherein the aqueous solution has a concentration in a range of 40 to 50 weight %.

7. The method recited in claim 1, wherein step (3) includes etching the wafer in a range of 0.3 to 0.8 μm on each side.

8. The method recited in claim 1, wherein step (3) includes cleaning with an acid, the acid being a mixed acid aqueous solution of hydrofluoric acid and nitric acid.

9. The method recited in claim 1, wherein the high-purity sodium hydroxide in step (4) is used as an alkali etching solution.

10. The method recited in claim 9, wherein an alkali component of the solution is in a range of 20 weight % to 70 weight %, preferably 40 weight % to 60 weight %, and more preferably in the range of 50 weight % to 55

11. The method recited in claim 10, wherein an alkali component of the solution is in a range of 40 weight % to 60 weight %.

12. The method recited in claim 11, wherein an alkali component of the solution is in a range of 50 weight % to 55 weight %.

13. The method recited in claim 1, wherein the high-purity sodium hydroxide used in step (4) has impurities including an elemental content of each of Cu, Ni, Mg and Cr of 1 ppb or less, an elemental content of each of Pb and Fe of 5 ppb or less, an elemental content of each of Al, Ca, Zn of 10 ppb or less, and a content of chloride, sulfate, phosphate, and nitride compounds of 1 ppm or less.
